(19) United States
(12) Patent Application Publication
(10) Pub. No.: US 2013/0302968 A1
(43) Pub. Date: Nov. 14, 2013

(54) MEMORY DEVICE AND METHOD FOR MANUFACTURING MEMORY DEVICE

(71) Applicant: NANYA TECHNOLOGY CORPORATION, TAO-YUAN HSIEN (TW)

(72) Inventors: SHIAN JYH LIN, TAIPEI COUNTY (TW); JEN JUI HUANG, TAOYUAN COUNTY (TW)

(21) Appl. No.: 13/946,704

(22) Filed: Jul. 19, 2013

Related U.S. Application Data
(62) Division of application No. 13/468,797, filed on May 10, 2012.

(51) Int. Cl. H01L 21/762

(52) U.S. Cl. CPC H01L 21/76224
USPC 438/424

(57) ABSTRACT

A memory device includes a substrate, first and second trench isolations, a plurality of line-type isolations, a first word line, and a second word line. The substrate comprises an active area that comprises source and drain regions. The first and second trench isolations extend parallel to each other. The plurality of line-type isolations define the active area together with the first and second trench isolations. The first word line extends across the active area. The first word line is formed in the substrate and adjacent to the first trench isolation. The first word line defines a first segment of the active area with the first trench isolation. The second word line extends across the active area. The second word line is formed in the substrate and adjacent to the second trench isolation. The second word line defines a second segment of the active area with the second trench isolation. The size of the first segment is substantially equal to the size of the second segment.

### BACKGROUND OF THE INVENTION

This is a divisional application of U.S. application Ser. No. 13/468,797, filed on May 10, 2012, the entirety of which is herein incorporated by reference.

### TECHNICAL FIELD

The present invention relates to a memory device and a method for manufacturing a memory device.

### BACKGROUND

DRAMs, one type of memory, typically comprise millions of identical circuit elements, known as memory cells. In one design, a pair of memory cells comprises three electrical devices: two storage capacitors and two access field transistors having a single source shared by the memory cells, two gates, two channels and two drains. Therefore, the pair of memory cells has two addressable locations, each storing one bit of data. A bit can be written to one addressable location through the transistor and read by sensing charges in the capacitor coupling to the drain from the source electrode. FIG. 1 shows a typical DRAM memory 1 of such design.

As shown in FIG. 1, the DRAM memory 1 is formed on a substrate 11, which has a plurality of active areas 12 that define the memory cells of the DRAM memory 1. The active area 12 contains field effect transistors and is surrounded by field isolations. In FIG. 1, the active area 12 has two drains 121 and one source 122 formed between the two drains 121. The drains 121 are for electrically coupling to storage capacitors. A plurality of digital lines 13 are formed in parallel, each electrically connecting to the sources 122 of a row of the active areas 12. Moreover, a plurality of pairs of word lines 14 are formed perpendicular to the digital lines 13. Each pair of word lines 14 extends across a column of active areas 12. Each word line 14 is coupled with the gate of a memory cell in the corresponding active area 12.

The word lines 14 are formed after the active areas 12 have been defined in the substrate 11. With current manufacturing technology, it is not easy to properly align the pair of word lines 14 with the corresponding column of active areas 12. As a result, the two regions 123 of each active area 12 located outside the corresponding word lines 14 may have different sizes, resulting in different performances of the two memory cells formed on the same active area.

### SUMMARY

According to one embodiment, a memory device comprises a substrate, first and second trench isolations, a plurality of line-type isolations, a first word line, and a second word line. The substrate comprises an active area that comprises source and drain regions. The first and second trench isolations extend parallel to each other. The plurality of line-type isolations define the active area together with the first and second trench isolations. The first word line extends across the active area. The first word line is formed in the substrate and adjacent to the first trench isolation. The first word line defines a first segment of the active area with the first trench isolation. The second word line extends across the active area. The second word line is formed in the substrate and adjacent to the second trench isolation. The second word line defines a second segment of the active area with the second trench isolation. The size of the first segment is substantially equal to the size of the second segment

In some embodiments, the first or second trench isolation has a material different from that of the line-type isolation.

In some embodiments, the first or second trench isolation has a depth different from that of the line-type isolation.

According to one embodiment, a method of manufacturing a memory device structure comprises forming a first layer on a substrate comprising a plurality of line-type active regions, forming a second layer on the first layer, patterning the second layer to form a plurality of lines crossing the line-type active regions and a plurality of first spaces separating the lines, depositing a first spacer material on the patterned second layer, filling the first spaces with fill material, removing the first spacer material thereby leaving a plurality of openings, forming a plurality of first trenches in the first layer through the plurality of openings, deepening the first trenches into the substrate, depositing gate dielectric material into the deepened first trenches, depositing conductive material in the deepened first trenches, forming an isolation structure in the deepened first trench on the conductive material, removing the second layer to expose upper portions of the isolation structures, forming a second spacer material on sidewalls of the isolation structures, defining a plurality of second spaces that separate the isolation structures in pairs, forming a plurality of second trenches in the substrate through the second spaces, and filling the second trenches with dielectric material.

The foregoing has outlined rather broadly the features and technical advantages of the present invention in order that the detailed description of the invention that follows may be better understood. Additional features and advantages of the invention will be described hereinafter, and form the subject of the claims of the invention. It should be appreciated by those skilled in the art that the conception and specific embodiment disclosed may be readily utilized as a basis for modifying or designing other structures or processes for carrying out the same purposes of the present invention. It should also be realized by those skilled in the art that such equivalent constructions do not depart from the spirit and scope of the invention as set forth in the appended claims.

### BRIEF DESCRIPTION OF THE DRAWINGS

The objectives and advantages of the present invention are illustrated with the following description and upon reference to the accompanying drawings in which:

FIG. 1 shows a typical DRAM memory;

FIG. 2 schematically demonstrates a memory device according to one embodiment of the present invention; and

FIGS. 3 to 20 schematically demonstrate the steps of a method for manufacturing a memory device according to one embodiment of the present invention.

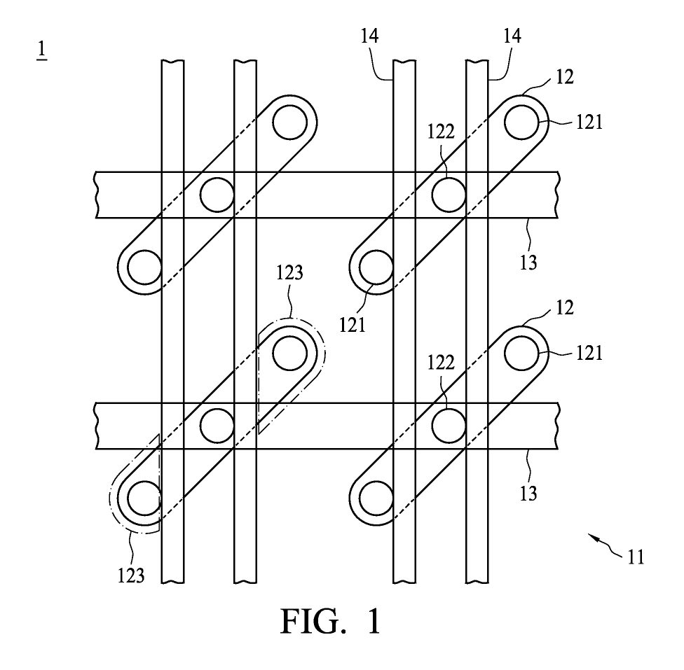

### DETAILED DESCRIPTION

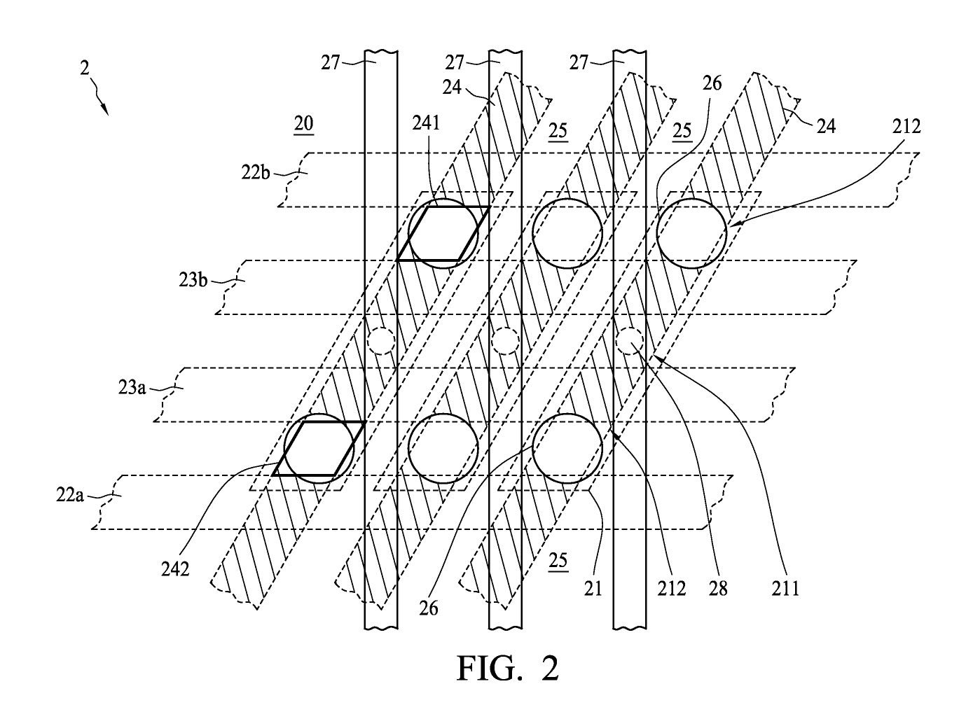

FIG. 2 schematically demonstrates a memory device 2 according to one embodiment. As illustrated in FIG. 2, the memory device 2 may comprise a plurality of active areas 21, a plurality of trench isolations 22a and 22b defining the active areas 21, and a plurality of word lines 23a and 23b extending across corresponding active areas 21.

The memory device 2 may be built from a substrate 20. The substrate 20 may be a semiconductor substrate. In some embodiments, the substrate 20 may comprise a p-type semiconductor substrate. In some embodiments, the substrate 20 may comprise a p-well semiconductor substrate. In some embodiments, the substrate 20 may comprise an n-type semiconductor substrate. In some embodiments, the substrate 20 may comprise an n-well semiconductor substrate.

A plurality of line-type active regions 24 are formed on the substrate 20. The line-type active regions 24 are formed in parallel along any desired direction, which is not limited to the configuration illustrated in FIG. 2. The line-type active region 24 can be used for forming a plurality of memory cells. Two adjacent active regions 24 may be isolated from each other by a line-type isolation 25. The line-type active regions 24 and the line-type isolations 25 can be patterned by a photolithography process. In some embodiments, the line-type isolation 25 may comprise oxide or nitride.

A plurality of trench isolations 22a and 22b are formed on or in the substrate 20, extending parallel to each other, defining a plurality of active areas 21 together with the line-type isolations 25. In some embodiments, each active area 21 may be adapted for forming two memory cells and comprises a shared source region 211 and two drain regions 212 for coupling to capacitors 26. The trench isolation 22a or 22b may be formed with a material that is the same as or different from the material for the line-type isolation 25. In some embodiments, the trench isolation 22a or 22b may comprise oxide or nitride. In some embodiments, the trench isolation 22a or 22b and the line-type isolation 25 are formed in different process steps so that the depth of the trench isolation 22a or 22b may be, but is not exclusively, different from the depth of the line-type isolation 25. A plurality of digital lines 27 can be formed perpendicular to word lines 23a and 23b, each electrically coupling to, but not limited to coupling to, a row of source regions 211. The digital line 27 can connect to a corresponding source region 211 through an electrically conductive plug 28. Two word lines 23a and 23b formed in the substrate 20 extend between two adjacent trench isolations 22a and 22b. Each word line 23a or 23b extends across a respective active area 24 and located substantially between a corresponding drain region 212 and a corresponding source region 211. The activation of the word line 23a or 23b allows charges to move between the digital line 27 and corresponding capacitors 26.

It should be noted that since it is impossible to create objects in the real world that, from the standpoint of abstract geometry, are perfectly parallel, perfectly equidistantly-spaced, perfectly vertical, or exactly half the width of a reference object, the term “substantially” has been used in both the specification and in the claims, to modify these adjectives and adjective phrases. That term should be understood to mean that even if perfect parallelism, verticality, equidistant spacing, and half-size reduction were the ultimate goal, they would be unachievable.

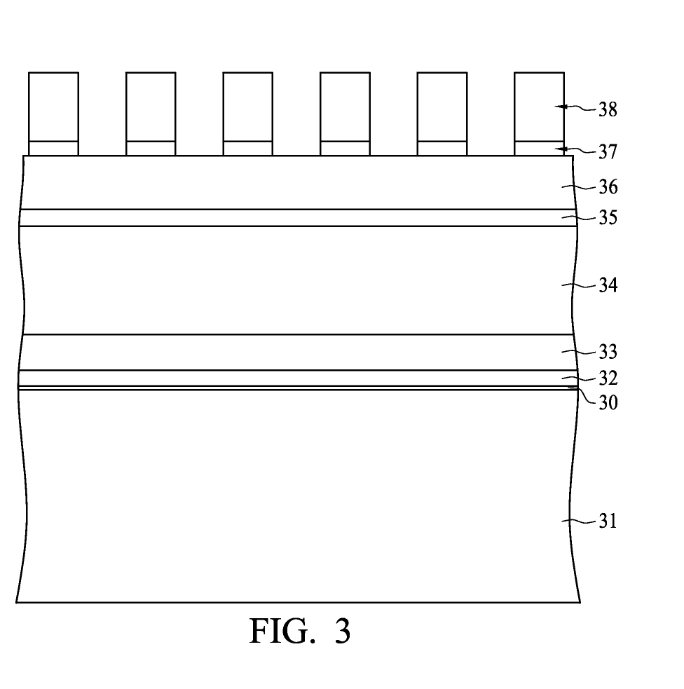

FIGS. 3 to 20 schematically demonstrate the steps of a method for manufacturing a memory device according to one embodiment. Referring to FIGS. 2 and 3, a substrate 31 with alternatively defined line-type active regions 24 and line-type isolations 25 is provided. Next, multiple layers are sequentially formed on the substrate 31, including a material layer 30, a material layer 32, a material layer 33, a material layer 34, a material layer 35, a material layer 36, and a material layer 37. Subsequently, a photoresist layer 38 is formed on the material layer 37 and then patterned to include a line-and-space pattern as shown in FIG. 3. In some embodiments, the line-and-space pattern may comprise lines and spaces both having an equal width. Thereafter, an etch process such as a dry etch process is performed to transfer the line-and-space pattern to the material layer 37. In some embodiments, the material layer 37 may comprise silicon oxynitride.

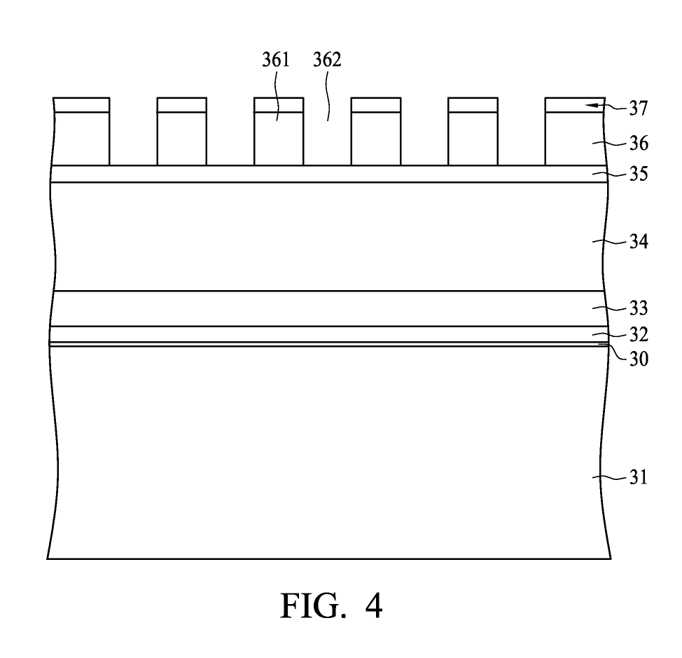

Referring to FIGS. 3 and 4, the photoresist layer 38 is removed or stripped. An etch process, for example a dry etch process, is performed to pattern the material layer 36 using the material layer 37 as a mask to form a patterned material layer 36 including a plurality of lines 361 crossing, but not necessarily obliquely to, the line-type active regions 24 and a plurality of spaces 362. In some embodiments, the material layer 36 may comprise carbon. In some embodiments, the material layer 36 is a carbon layer, which includes CₓH_{y}. In some embodiments, the material layer 36 comprises carbon-contained material. In some embodiments, the material layer 36 may be transparent.

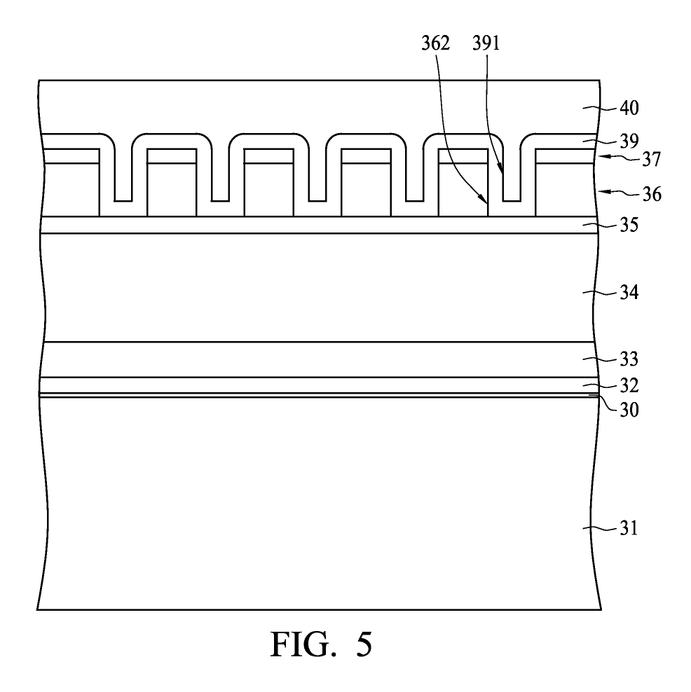

Referring to FIG. 5, a deposition layer 39 such as an oxide layer is formed on the patterned material layer 36. In some embodiments, the deposition layer 39 is deposited by atomic layer deposition (ALD). In some embodiments, the deposition layer 39 comprises atomic layer deposition oxide.

Fill material 40 is deposited on the deposition layer 39, filling the spaces 391 defined by the deposition layer 39 and covering the deposition layer 39. In some embodiments, the fill material 40 may comprise amorphous silicon. In some embodiments, the fill material 40 is deposited by an amorphous silicon deposition at a temperature of less than 500° C. . In alternate embodiments, photoresist or anti-reflective coating (ARC) material is used as the fill material 40 to refill the spaces 391 and cover the deposition layer 39.

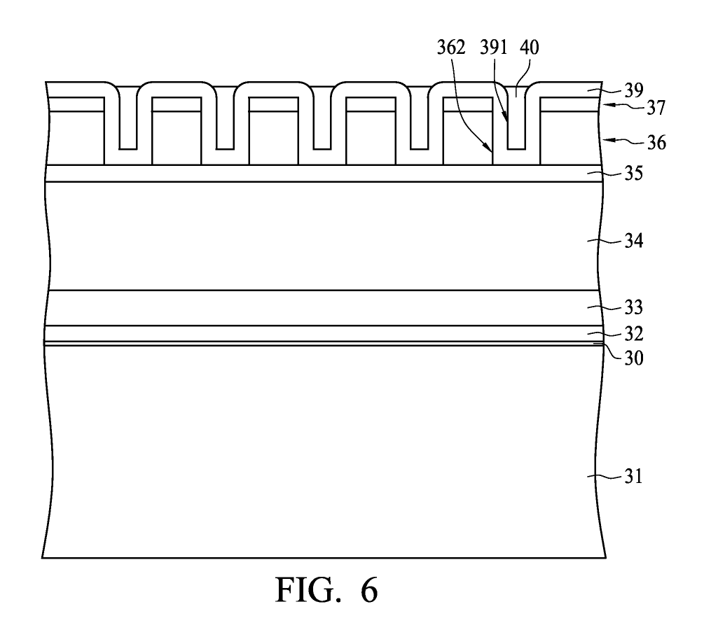

As shown in FIG. 6, in the embodiments of using material such as amorphous silicon to cover the deposition layer 39, a chemical mechanical polishing (CMP) or dry etching process is employed to remove a portion of the deposition layer 40 and stopped when the deposition layer 39 is reached or shortly thereafter, for example. Remnant fill material 40 is left in the spaces 362 of the material layer 36.

Alternatively, in the embodiments of using material such as photoresist or ARC layer to cover the deposition layer 39, a photoresist etch back process is carried out. The deposition layer 39 is used as a stop layer to determine when the photoresist etch back process is to be stopped.

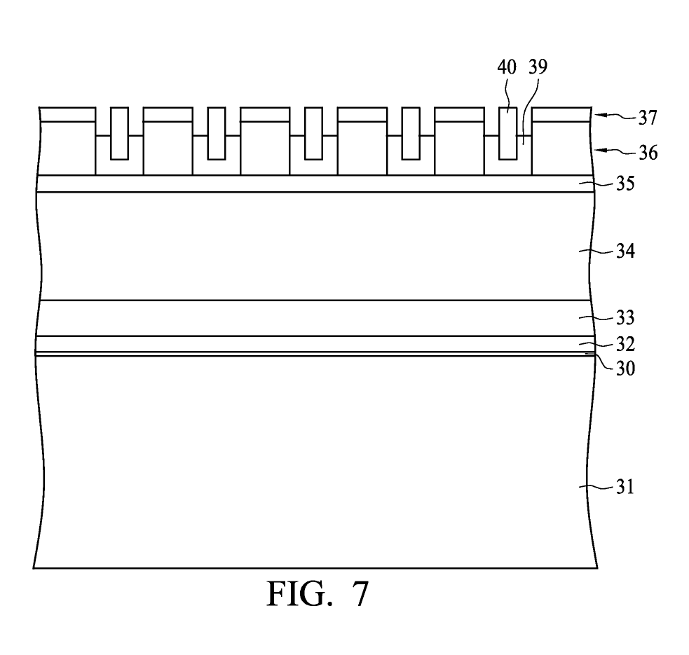

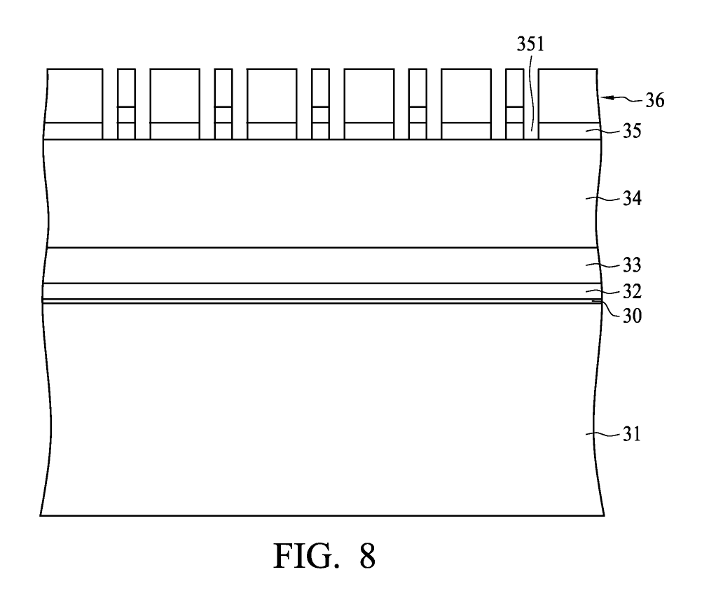

Referring to FIG. 7, when the deposition layer 39 is an oxide layer, a portion of the deposition layer 39 can be removed by a diluted hydrofluoric acid (DHF) process. The etchant may be hydrofluoric acid that has been diluted with water with a dilution ratio of, for example, 500:1 of water to hydrofluoric acid. Next, referring to FIGS. 7 and 8, the remnant deposition layer 39 is removed by a recess etch process, subsequently followed by a breakthrough etch applied for removing exposed portions of the material layer 35 to form a material layer 35 with a plurality of openings 351. In some embodiments, the material layer 35 may comprise oxynitride.

In some embodiments, the material layer 34 may comprise carbon. In some embodiments, the material layer 34 is a carbon layer. In some embodiments, the material layer 34 comprises carbon-contained material. In some embodiments, the material layer 34 may be transparent.

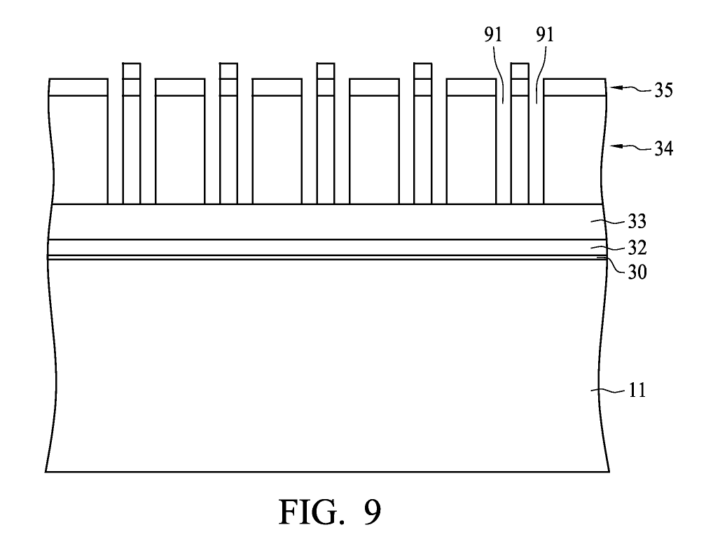

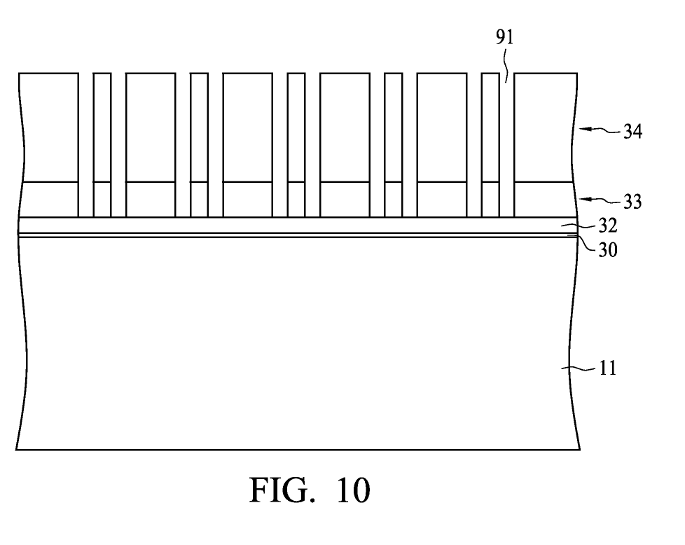

Referring to FIG. 9, when the material layer 34 comprises carbon, an etch process such as a dry etch process is performed to form a plurality of trenches 91 in the material layer 34. In some embodiments, the material layer 36 and the material layer 34 are formed by the same material, and the etch process removes the material layer 36 while the plurality of trenches 91 are being formed. After the plurality of trenches 91 have been formed, an etch process is applied to remove the material layer 35 to expose the material layer 34 and portions of the material layer 33 exposed in the trenches 91, as shown in FIG. 10. In some embodiments, the material layer 33 comprises nitride.

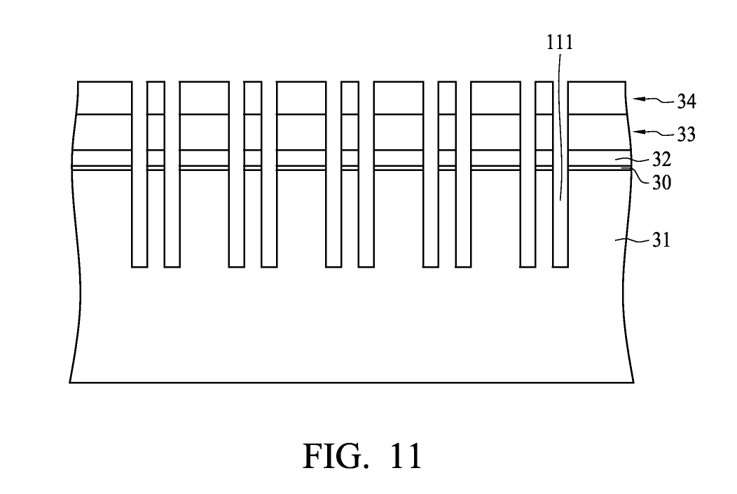

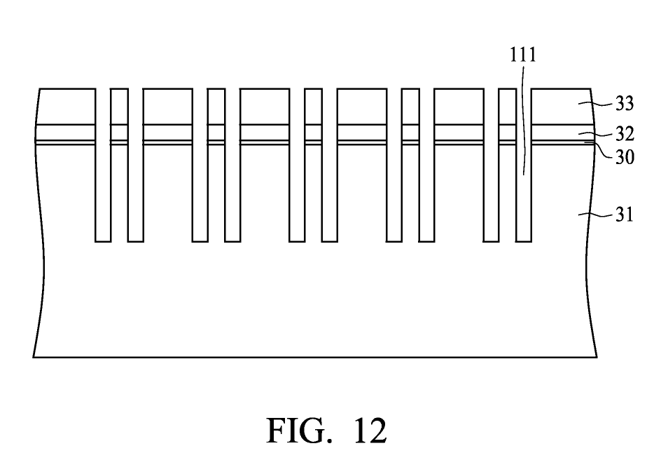

As illustrated in FIG. 11, with the material layer 34 as a mask, at least one recess etch process is performed to etch down further through the material layer 32 and the material layer 30, penetrating into the substrate 31 for deepening the trenches 91, forming deepened trenches 111. Thereafter, the material layer 34 is removed or stripped as shown in FIG. 12. In some embodiments, the material layer 32 comprises polysilicon. In some embodiments, the material layer 30 comprises oxide.

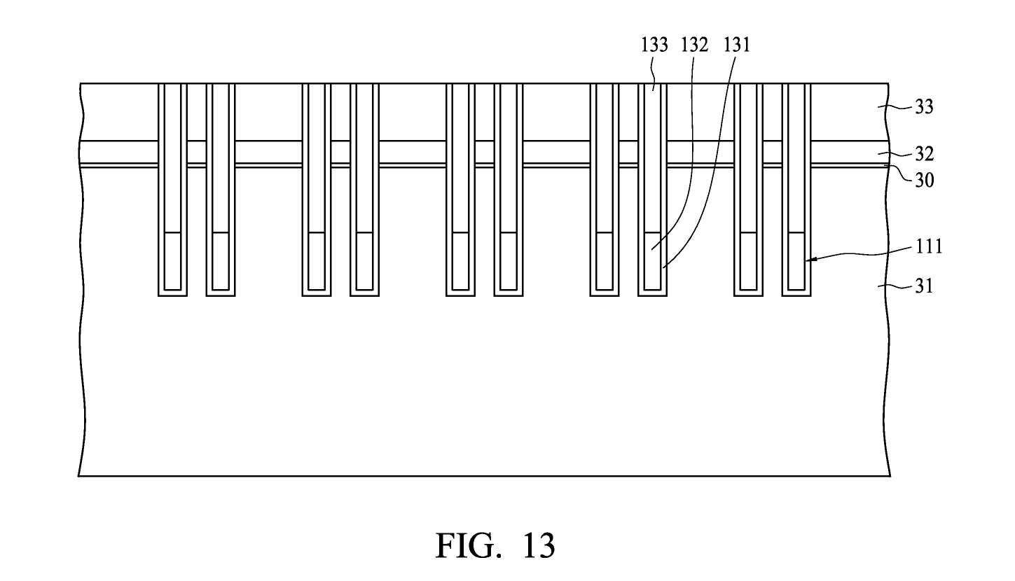

Referring to FIG. 13, a dielectric material is disposed into the deepened trenches 111. In the present invention, an oxidation process, for example ISSG (in-situ steam generation) process, is performed to form an oxide layer 131 including a portion formed on RAD (recessed access device) gate structures.

Next, conductive material 132 used for forming word lines is deposited, followed by performing a recess etch process to remove an upper portion of conductive material 132, leaving the other portion of conductive material 132 in the trenches 111 constituted as word lines.

Thereafter, an insulating material is filled into the trenches 91 and 111. In some embodiments, an oxide deposition process such as a TEOS (tetraethylorthosilicate) deposition process is performed to fill the trenches 91 and 111, and an annealing process is optionally carried out to densify the TEOS oxide layer. Next, the portion of the TEOS oxide layer above the material layer 33 is removed, and as a result, an isolation structure 133 is formed in each trench 91 and 111 on a corresponding conductive material.

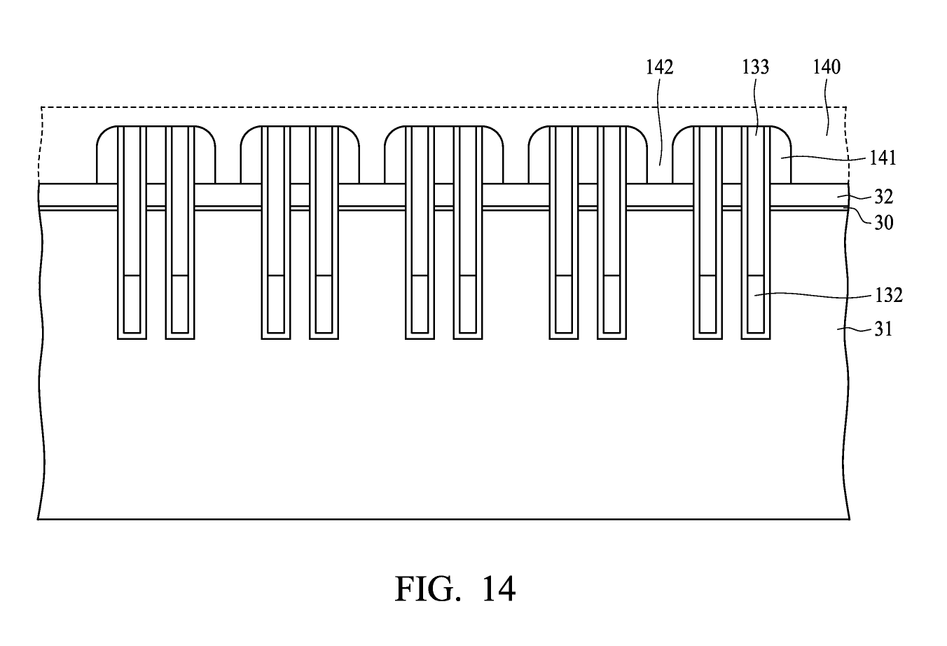

As shown in FIG. 14, the material layer 33 is removed, exposing upper portions of isolation structures 133 and the material layer 32. The isolation structures 133 are not arranged equally. Two spaces with different widths alternatively separate the isolation structures 133. A layer 140 is deposited on and filled into structures 133. Next, the layer 140 is etched to form spacers 141. As a result, the spacers 141 define a plurality of spaces 142 separating the upper portions of isolation structures 133 in pairs. In some embodiments, the spacer 141 comprises oxide. In some embodiments, the spacer 141 comprises the atomic layer deposition oxide. In some embodiments, the spacer 141 is formed by atomic layer deposition (ALD).

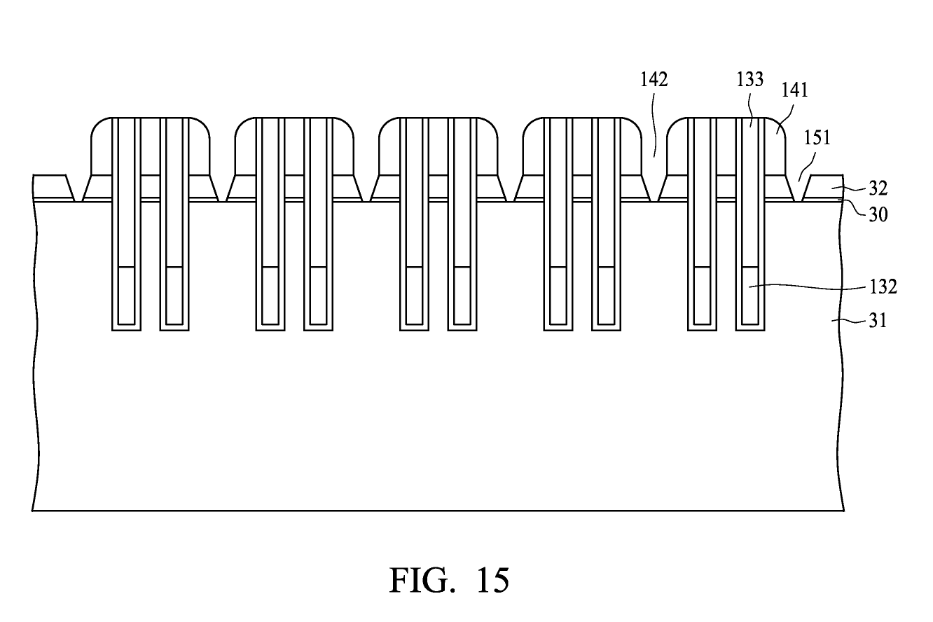

Referring to FIG. 15, the exposed portions of the material layer 32 and corresponding underlying portions of the material layer 30 are removed. In some embodiments, the exposed portions of the material layer 32 and corresponding underlying portions of the material layer 30 can be removed by an etch process through the spaces 142. In some embodiments, the material 32 comprises polysilicon and the spacer 141 comprises oxide, and the exposed portions of the material layer 32 and corresponding underlying portions of the material layer 30 are removed by a selective etch process. In some embodiments, the material layer 30 comprises oxide.

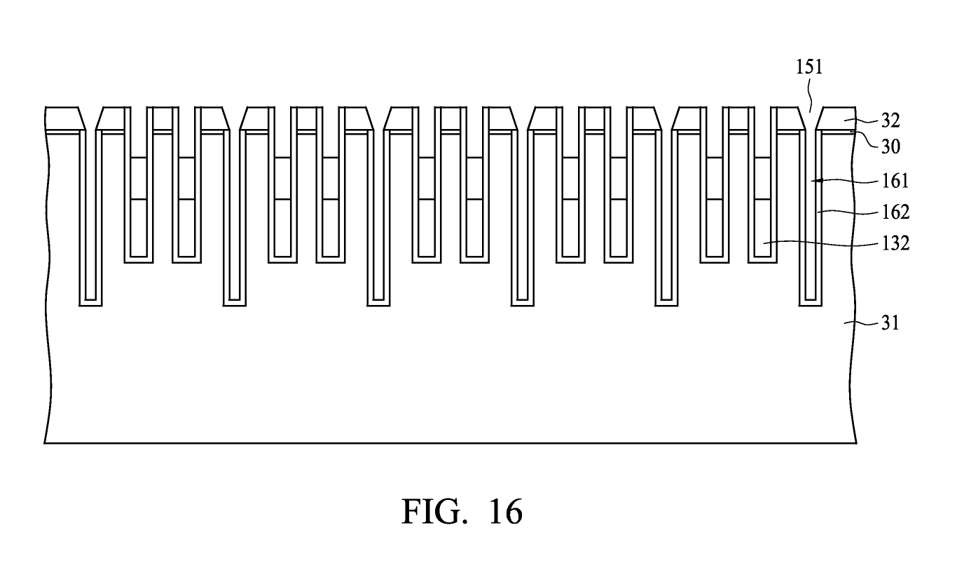

Referring to FIGS. 15 and 16, after the exposed portions of the material layer 32 and corresponding underlying portions of the material layer 30 are removed, a plurality of openings 151 are formed, exposing a plurality of portions of the material layer 31. Next, the material layer 31 is etched through the openings 151, forming a plurality of trenches 161. Next, sidewall oxide is formed in trenches 161 by ISSG (in-situ steam generation) followed by an isolation fill process named spin-on-deposition or nitride fill process.

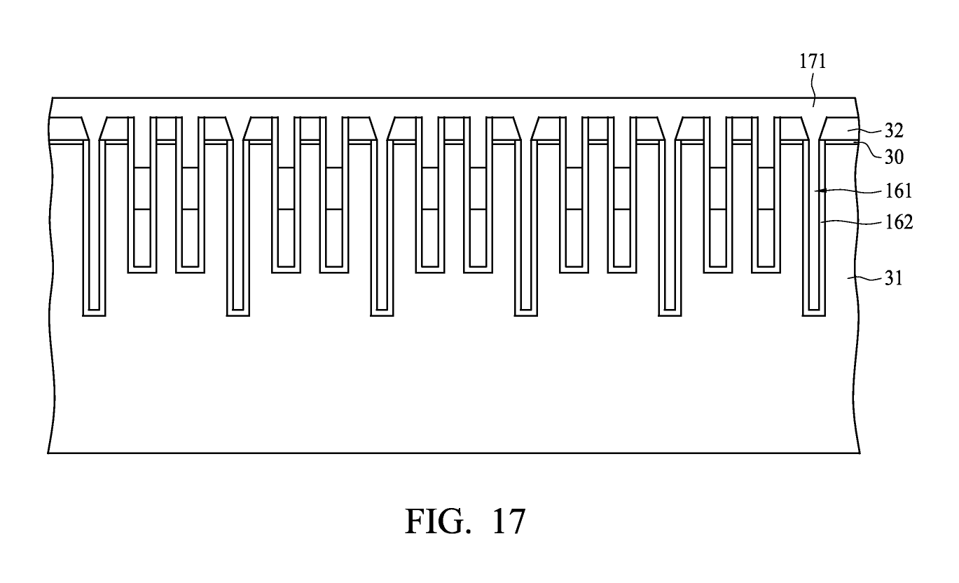

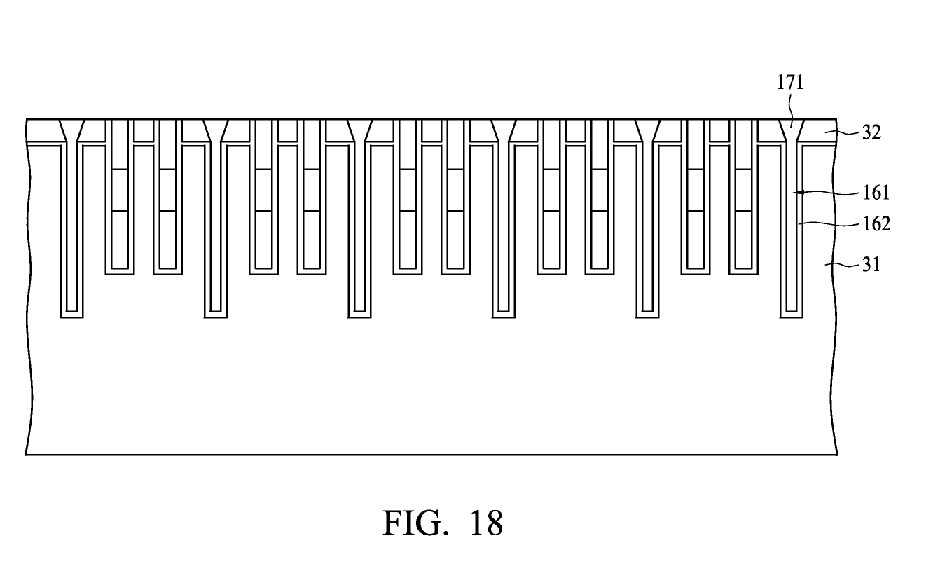

As shown in FIG. 17, a material 171 such as dielectric material, for example a material comprising nitride, is deposited and covers the material layer 32. Next, the material 171 above the material layer 32 is removed or deglazed as shown in FIG. 18.

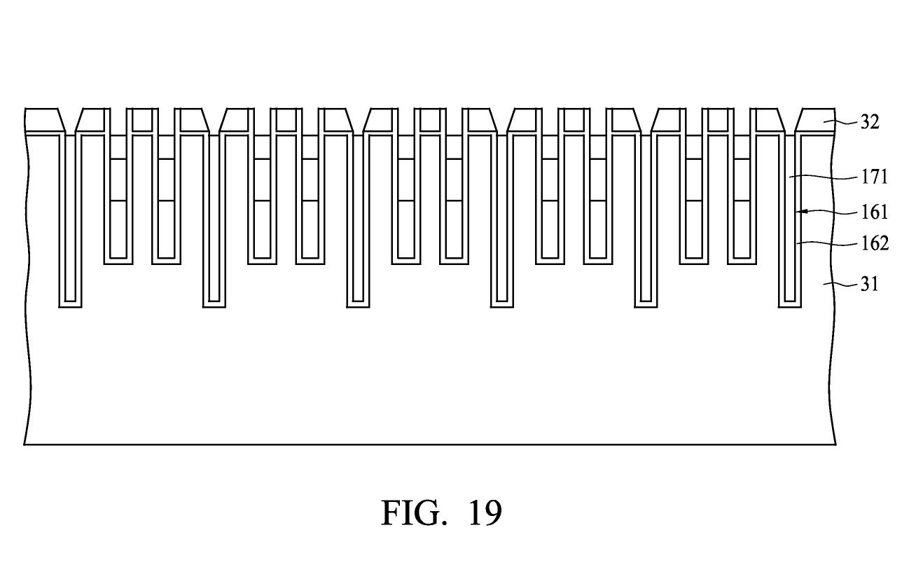

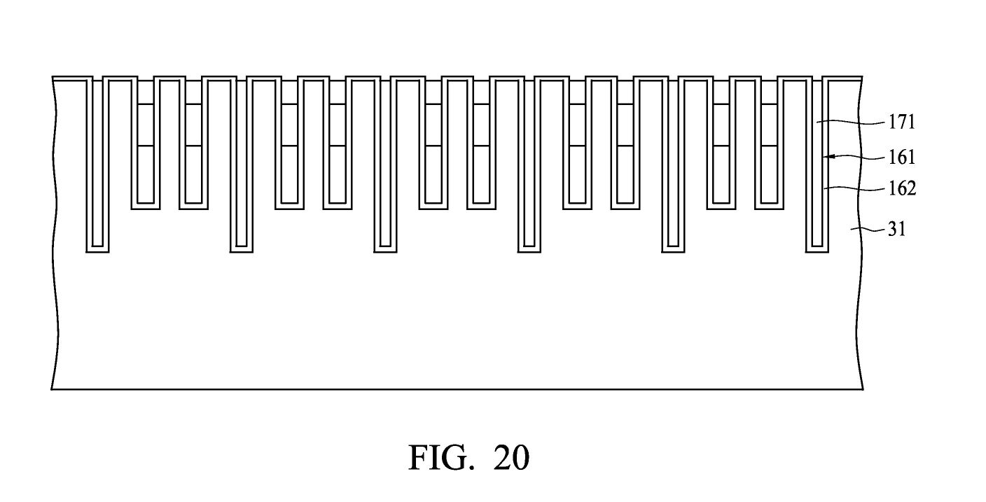

Referring to FIGS. 19 and 20, the material 171 substantially above the material layer 31 is removed or deglazed. A plurality of trench isolations are formed accordingly.

As shown in FIG. 2, in some embodiments, spacers that can be accurately formed is deposited on the sidewalls of isolation structures correspondingly located above word lines to position trench isolations 22a and 22b that define active areas 21 from line-type active regions 26. Consequently, a segment 241 of the active area 21 between the word line 23b and the trench isolation 22b can be substantially equal in size to the segment 242 of the active area 21 between the word line 23a and the trench isolation 22a, or alternatively the distance between the word line 23b and the trench isolation 22b is substantially equal to that of the word line 23a and the trench isolation 22a. Furthermore, the trench isolations 22a and 22b and the line-type isolations 25 are formed by different processes. Therefore, the trench isolation 22a or 22b and the line-type isolation 25 may have different depths, and the trench isolation 22a or 22b and the line-type isolation 25 can be even formed with different materials.

Although the present invention and its advantages have been described in detail, it should be understood that various changes, substitutions and alterations can be made herein without departing from the spirit and scope of the invention as defined by the appended claims. For example, many of the processes discussed above can be implemented in different methodologies and replaced by other processes, or a combination thereof.

Moreover, the scope of the present application is not intended to be limited to the particular embodiments of the process, machine, manufacture, composition of matter, means, methods and steps described in the specification. As one of ordinary skill in the art will readily appreciate from the disclosure of the present invention, processes, machines, manufacture, compositions of matter, means, methods, or steps, presently existing or later to be developed, that perform substantially the same function or achieve substantially the same result as the corresponding embodiments described herein may be utilized according to the present invention. Accordingly, the appended claims are intended to include within their scope such processes, machines, manufacture, compositions of matter, means, methods, or steps.

What is claimed is:

1. A method of manufacturing a memory device structure, comprising steps of:
forming a first layer on a substrate comprising a plurality of line-type active regions;
forming a second layer on the first layer;
patterning the second layer to form a plurality of lines crossing the line-type active regions and a plurality of first spaces separating the lines;
depositing first spacer material on the patterned second layer;
filling the first spaces with fill material;
removing the first spacer material, thereby leaving a plurality of openings;
forming a plurality of first trenches in the first layer through the plurality of openings;
deepening the first trenches into the substrate;
depositing gate dielectric material into the deepened first trenches;
depositing conductive material in the deepened first trenches;
forming an isolation structure in the deepened first trench, on the conductive material;
removing the second layer to expose upper portions of the isolation structures;
forming a second spacer material on sidewalls of the isolation structures, defining a plurality of second spaces that separate the isolation structures in pairs;
forming a plurality of second trenches in the substrate through the second spaces; and
filling the second trenches with dielectric material.

2. The method of claim 1, wherein the step of patterning the second layer comprises a step of patterning the second layer by a patterned material layer comprising silicon oxynitride.

3. The method of claim 1, further comprising a step of forming a silicon oxynitride layer between the first and second layers.

4. The method of claim 3, further comprising a step of patterning the silicon oxynitride layer using the patterned second layer.

5. The method of claim 1, further comprising a step of forming a polysilicon layer between the substrate and the first layer.

6. The method of claim 5, further comprising a step of selectively etching the polysilicon layer through the second spaces.

7. The method of claim 1, wherein the first or second spacer material comprises oxide.

8. The method of claim 1, wherein the first or second layer comprises carbon and CₓH_{y}.

9. The method of claim 1, wherein the fill material comprises amorphous silicon.

10. The method of claim 1, wherein the dielectric material comprises nitride.
